(19) United States
(12) Patent Application Publication
(10) Pub. No.: US 2014/0263275 A1
(43) Pub. Date: Sep. 18, 2014

(54) ROTATION ENABLED MULTIFUNCTIONAL HEATER-CHILLER PEDESTAL

(71) Applicant: Applied Materials, Inc., Santa Clara, CA (US)

(72) Inventors: Tuan Anh NGUYEN, San Jose, CA (US); Sanjeev BALUJA, Campbell, CA (US); Amit Kumar BANSAL, Sunnyvale, CA (US); Juan Carlos ROCHA-ALVAREZ, San Carlos, CA (US)

(73) Assignee: Applied Materials, Inc., Santa Clara, CA (US)

(21) Appl. No.: 14/180,959

(22) Filed: Feb. 14, 2014

Related U.S. Application Data
(60) Provisional application No. 61/793,798, filed on Mar. 15, 2013.

(51) Int. Cl. H01L 21/683; G01K 7/02

(52) U.S. Cl. CPC H01L 21/683; G01K 7/023
USPC 219/446.1; 374/179

(57) ABSTRACT

Embodiments of the present disclosure provide apparatus and methods for improving process uniformity. Particularly, embodiments of the present disclosure provide a rotatable temperature controlled substrate support for a semiconductor processing chamber. The rotatable temperature controlled substrate support includes one or more heating elements, one or more temperature sensors and cooling channels for circulating a cooling/heating fluid in the rotatable temperature controlled substrate support. One embodiment of the present disclosure includes a thermocouple extension assembly for extending cold junctions of the thermocouple in the substrate support away from the substrate support. The thermocouple extension assembly includes extension cords formed from materials matching with the materials of thermocouple.

### CROSS-REFERENCE TO RELATED APPLICATIONS

This application claims priority to U.S. Provisional Patent Application Ser. No. 61/793,798, filed on Mar. 15, 2013, which herein is incorporated by reference.

### BACKGROUND

1. Field

Embodiments of the present disclosure relate to apparatus and methods for processing semiconductor substrates. More particularly, embodiments of the present disclosure relate to rotatable and temperature controlled substrate support for semiconductor substrate processing.

2. Description of the Related Art

During manufacturing of semiconductor devices, a substrate is usually processed in a processing chamber, where deposition, etching, thermal processing may be performed to the substrate. When a process requires the substrate being processed to be heated to and maintained at a high temperature, it is desirable to have a substrate support with heaters, cooling channels and temperature sensors. Traditionally, such temperature controlled substrate supports are not rotatable to accommodate connections to cooling fluid, electronic connections to heaters and sensors. However, the non-rotatable nature of the substrate support exposes the substrate to non-uniformity of the processing chamber, such as non-symmetry of the processing chamber and non-symmetry of fluid flow in the processing chamber.

Additionally, traditional substrate supports usually use thermocouples as temperature sensors. However, the thermocouples stemming from central shafts of traditional substrate supports must pass through an electrical union to enable rotatable motion, and this leads to inaccuracies in temperature readings when thermal management of the junctions/extensions of the thermocouples are not considered. Thermal management of the junctions considers the absolute temperature and its stability over time, the accuracy and precision of the readings are directly coupled to this.

Therefore, there is a need for substrate supports for providing improved temperature control and improved process uniformity.

### SUMMARY

Embodiments of the present disclosure generally provide apparatus and methods for improving process uniformity of a substrate being processed.

One embodiment of the present disclosure provides a thermocouple extension. The thermocouple extension includes a first extension having a first end for receiving a first connector of a thermocouple and a second end positioned away from the first end, wherein the first extension and the first connector are formed from the same material, and a second extension having a first end for receiving a second connector of the thermocouple and a second end positioned away from the first end, wherein the second extension and the second connector are formed from the same material.

Another embodiment of the present disclosure provides a rotatable substrate support assembly. The rotatable substrate support assembly comprises a substrate support body having a substrate supporting surface. The substrate support body comprises one or more sensors disposed in the substrate support body, and one or more heating elements disposed in the substrate support body. The rotatable substrate support assembly further comprises a shaft extending from the substrate support body, wherein one or more cooling channels are formed through the substrate support body and the shaft, and one or more vacuum channels are form through the substrate support body and the shaft, and an extension assembly coupled to the shaft, wherein the extension assembly is configured to rotatably couple a power source with the one or more heaters, rotatably couple a data collector with the one or more sensors, rotatably couple a fluid source with the cooling channels, rotatably couple a vacuum source with the vacuum channels, and rotatably couple a rotation motor with the shaft.

Another embodiment of the present disclosure provides a substrate support assembly. The substrate support assembly comprises a substrate support body having a substrate supporting surface, a shaft extending from the substrate support body, wherein the shaft has a first end attached to the substrate support body and a second end away from the substrate support body, and the shaft is hollow having an inner volume extending from the first end to the second end, a thermocouple attached to the substrate support body, wherein first and second connectors of the thermocouple extend down the inner volume to the second end of the shaft, and a thermocouple extension attached to second end of the shaft. The thermocouple extension comprises a first extension having a first end for receiving the first connector of the thermocouple and a second end positioned away from the first end, wherein the first extension and the first connector are formed from the same material, and a second extension having a first end for receiving the second connector of the thermocouple and a second end positioned away from the first end, wherein the second extension and the second connector are formed from the same material.

Yet another embodiment of the present disclosure provides a semiconductor processing chamber. The chamber comprises a chamber body defining a processing volume, a substrate support body disposed in the processing volume for supporting a substrate thereon. The substrate support body comprises one or more sensors disposed in the substrate support body, and one or more heating elements disposed in the substrate support body. The chamber further comprises a shaft extending outside the processing volume from the substrate support body through an opening of the chamber body. The one or more cooling channels are formed through the substrate support body and the shaft, and one or more vacuum channels are form through the substrate support body and the shaft. The processing chamber further includes an extension assembly disposed outside the processing volume and coupled to the shaft. The extension assembly is configured to rotatably couple a power source with the one or more heaters, a data collector with the one or more sensors, a fluid source with the cooling channels, and a vacuum source with the vacuum channels. The processing chamber further includes a rotation motor having a rotor coupled with the extension assembly and a stator coupled to a bracket and a vertical actuator coupled to the bracket, wherein the vertical actuator moves the substrate support body, the shaft, the extensions assembly and the rotation motor vertically.

One embodiment of the present disclosure provides a connection block. The connection block includes a block body, and at least one pair of thermocouple connectors attached to the block body. Each pair of the thermocouple connectors comprises a first connector formed from a first conductive material, and a second connector formed from a second conductive material different from the first conductive material, wherein the first and second conductive materials correspond to conductive materials used in a thermocouple.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic sectional view of a processing chamber according to one embodiment of the present disclosure.

FIG. 1B is a schematic sectional view of the processing chamber of FIG. 1A in a substrate loading/unloading position.

FIG. 2 is a schematic perspective view of a substrate support assembly according to one embodiment of the present disclosure.

FIG. 3A is a schematic sectional view of a substrate support assembly having a thermocouple according to one embodiment of the present disclosure.

FIG. 3B is a partial sectional view of a substrate support assembly having a thermocouple according to another embodiment of the present disclosure.

FIG. 4A is a schematic perspective view of a connection block attached to a substrate support assembly according to one embodiment of the present disclosure.

FIG. 4B is a schematic perspective view of a connection block matching the connection block of FIG. 4A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure provide apparatus and methods for improving process uniformity. Particularly, embodiments of the present disclosure provide a rotatable temperature controlled substrate support for a semiconductor processing chamber.

The rotatable temperature controlled substrate support includes one or more heating elements, one or more temperature sensors and cooling channels for circulating a cooling/heating fluid in the rotatable temperature controlled substrate support. The rotatable temperature controlled substrate support includes a fluid union configured to connecting a non-rotatable fluid inlet/outlet from a fluid source to cooling channels in the rotatable temperature controlled substrate support. The rotatable temperature controlled substrate support also includes an electrical union for coupling with non-rotating power sources and electronic connections.

In one embodiment, the one or more temperature sensors include a thermocouple. One embodiment of the present disclosure includes a thermocouple extension assembly for extending cold junctions of the thermocouple in the substrate support away from the substrate support. The thermocouple extension assembly includes extension cords formed from materials matching with the materials of thermocouple.

FIG. 1A is a schematic sectional view of a processing chamber 100 according to one embodiment of the present disclosure. The processing chamber 100 includes a substrate support assembly 130 that is rotatable and temperature controlled to improve process uniformity. The processing chamber 100 may be used for deposition, etching or thermal processing. In one embodiment, the processing chamber 100 may be used for performing chemical vapor deposition.

The processing chamber 100 includes chamber walls 110, a chamber bottom 112 and a lid assembly 114 defining a processing volume 118. The substrate support assembly 130 is disposed in the processing volume 118 for supporting a substrate 102 thereon. The lid assembly 114 may include a showerhead 116 for distributing one or more processing as from a gas source 124 to the processing volume 118. A vacuum system 128 may be coupled to the processing volume 118 for pumping the processing volume 118. A slit valve opening 120 may be formed through the chamber walls 110 to allow passage of substrates. A slit valve door 122 may be coupled to the chamber wall 110 to selectively open or close the slit valve opening 120. Optionally, the lid assembly 114 may be UV transparent and a UV assembly 126 may be disposed over the lid assembly 114 for performing UV treatment, such as UV annealing, on the substrate 102.

The substrate support assembly 130 generally includes a support body 132 having a substantially planar supporting surface 134 on which the substrate 102 is disposed. The support body 132 may be a circular disk. A shaft 136 extends from a backside of the support body 132 along a central axis 138. The shaft 136 extends out the processing volume 118 through an opening 140 on the chamber bottom 112. The shaft 136 is further connected to driving devices to vertically move and/or rotate the shaft 136 and support body 132. The shaft 136 may be hollow having an inner volume 148 to accommodate electrical connector 196 and/or sensor connectors 198.

The substrate support assembly 130 includes one or more sensors 142 embedded in the support body 132. In one embodiment, the one or more sensors 142 may include one or more temperature sensors, such as a thermocouple, a resistance temperature detector, a thermistor, or any other applicable temperature sensor, disposed on various locations of the support body 132 to measure temperatures at the various locations. In one embodiment, the one or more sensors 142 includes an inner thermocouple 142a disposed near the central axis 138 of the support body 132, and an outer thermocouple 142b disposed away from the central axis 138. The one or more sensors 142 may have connectors extending through the inner volume 148 of the shaft 136 towards a data collector 156.

The substrate support assembly 130 further includes one or more heaters 144 embedded in the support body 132. In one embodiment, the one or more heaters 144 includes an inner heater for heating a region close to the central axis 138 and an outer heater for heating a region radially away from the central axis 138. The one or more heaters 144 may be connected to a power source 158 through cables disposed in the inner volume 148 of the shaft 136. In one embodiment, the one or more heaters 144 may be independently controllable and each of the one or more heaters 144 is positioned to heat one of multiple heating zones. Each of the one or more sensors 142 may be temperature sensors positioned to measure temperatures in a corresponding heat zone and provides closed loop control to the one or more heaters 144.

The support body 132 also includes cooling channels 146 for circulating a cooling/heating fluid through the support body 132 to provide cooling/heating to the support body 132 and the substrate 102 thereon. A portion of the cooling channels 146 may be formed through sidewall of the shaft 136 to further connect with a cooling/heating fluid source 152.

The support body 132 may include a plurality of vacuum channels 150 open to the substrate supporting surface 132 of the support body 132. The plurality of vacuum channels 150 may be used to secure the substrate 102 on the substrate supporting surface 132 by vacuum chuck. A portion of the vacuum channels 150 may be formed through sidewall of the shaft 136 to further connect to a vacuum source 154.

The processing chamber 100 further includes a frame assembly 160. The substrate support assembly 130 is movably connected with the frame assembly 160. In one embodiment, the frame assembly 160 may include a backing plate 162 securely attached to the chamber bottom 112 or the chamber walls 110. A flange 166 is connected to the backing plate 162 through a plurality of columns 164. A linear guide 168 is attached to the flange 166. A vertical actuator 172 drives a sliding block 170 along the liner guide 168. The sliding block 170 is coupled with the substrate support assembly 130 to move the substrate support assembly 130 vertically.

Outside the processing volume 118, the shaft 136 is further connected to various extensions for housing adaptors, coupling with a rotation motors, and unions for cooling fluid, vacuum and electrical connection to enable rotation. In one embodiment, the shaft 136 is connected to an adapter extension 174. The adaptor portion 174 is attached to the shaft 136. The adaptor extension 174 may house adaptors 196 and 198 for connecting the one or more sensors 142 and one or more heaters 144 to external connectors 199.

In one embodiment, the shaft 136 further connects with a vacuum extension 176 configured to connect with a vacuum union 188, a rotation extension 178 configured to connected with a rotation motor 190, a cooling fluid extension 180 configured to connect with a cooling fluid union 192, and an electric extension 182 connected to an electrical union 194. The vacuum union 188, cooling fluid union 192 and electrical union 194 enable the shaft 136 and extensions 176, 178 and 182 to rotate while maintaining connections of vacuum, cooling fluid, and electrical signals.

The processing chamber 100 further includes a shield 186 surrounding the shaft 136 without contacting the shaft 136 and the adaptor extension 174. A bellows 184 is disposed between the backing plate 162 and the shield 186. The bellows 184 and the shield 186 seal the shaft 136 from external environment while allowing the shaft 136 to rotate and move vertically.

A bracket 104 is fixedly attached to the sliding block 170. A stator of the rotation motor 190 may be coupled to the bracket 104. An outer portion 106a of a bearing 106 is coupled to the bracket 104. An inner portion 106b of the bearing 106 supports one of the extensions 174, 176, 178. The bearing 106 allows the rotation motor 190 to rotate the shaft 136 relative to the bracket 104, the sliding block 170 and the frame assembly 160.

FIG. 1B is a schematic sectional view of the processing chamber 100 of FIG. 1A in a substrate loading/unloading position. The substrate support assembly 130 is lowered from the processing position shown in FIG. 1A by the vertical actuator 172. The lowered position of the support body 132 allows lifting pins 108 to extend above the substrate supporting surface 134 to lift the substrate 102 from the substrate support assembly 130. The substrate support 130 may then be unloaded from the processing chamber 100 through the slit valve opening 120.

During operation, the vertical actuator 172 may move the sliding block 170 vertically down along with the bracket 104 which the substrate support assembly 130 down to the loading/unloading position as shown in FIG. 1B. The substrate 104 may be loaded and the slit valve door 122 closed. The vertical actuator 172 then moves the sliding block 170, the bracket 104 and the substrate support assembly 130 up to the processing position shown in FIG. 1A. The rotation motor 190 then rotates the rotation extension 178 about the center axis 138. The substrate 102 rotates with the rotation extension 178 which if fixedly connected to the shaft 136 and the support body 132. The rotation of the substrate 102 enables uniform exposure of the substrate 102 to processing conditions in the processing volume 118. The vacuum extension 176 rotates relative to the vacuum union 188, the fluid extension 180 rotates relative to the cooling fluid union 192, and the electrical extension 182 rotates relative to the electrical union 194. While the substrate 102 rotates, the substrate 102 may be vacuum chucked to the substrate supporting surface 134 by the vacuum source 154 through the vacuum union 154 and the vacuum channel 152, the power source 158 maintains connection with the one or more heaters 144 through the electrical union 194 and the electrical connectors 196, the one or more sensors 142 may be monitors by the data collector 156 through the electrical union 194, the external connectors 199 and the connectors 198, and cooling/heating fluid may be circulated in the cooling channels 146 through the cooling fluid union 152.

Rotation of the substrate 102 during processing enables active temperature control at all time, thus improve process uniformity.

FIG. 2 is a schematic perspective view of a rotatable substrate support assembly 200 according to one embodiment of the present disclosure. The shaft 136 and extensions 174, 176, 178, 180 and 182 are secured to one another to move vertically or rotate about the central axis 138 together. The extensions 174, 176, 178, 170 and 182 may be arranged in different orders according to different designs.

The shaft 136 and extensions 174, 176, 178, 180 and 182 may be hollow to house connectors 202, 204, 206 for sensors and heaters from the substrate support body 132 to the electrical extension 182. The connectors 202, 204, 206 may extend through sidewall of the electric extension 182 to connect with an electrical union. Even though, each of the connectors 202, 204, 206 are shown as one continuous conductive line, the connectors 202, 204, 206 may include multiple portions with adaptors or junctions.

The vacuum channels 146 are formed through sidewalls of the shaft 136, the adapter extension 174, and the vacuum extension 176. The vacuum channels 150 may form an inlet and an outlet at outer surface of the vacuum extensions 176 to connect with a vacuum union.

The cooling channels 146 are formed through sidewalls of the shaft 136, the adapter extension 174, the vacuum extension 176, the rotation extension 179 and the cooling extension 180. The cooling channels 146 may form an inlet and an outlet at outer surface of the cooling extensions 186 to connect with a cooling fluid union.

Embodiments of the present disclosure also provide apparatus and method for improving accuracy of thermocouple measurement particularly at high temperature range.

FIG. 3A is a schematic sectional view of a substrate support assembly 300 having a thermocouple extension 328 according to one embodiment of the present disclosure. The substrate support assembly 300 may include a support body 302, a shaft 304 connected to the support body 302. In one embodiment, the support body 302 may be heated by one or more heaters (not shown) or by plasma or external heating sources during processing. One or more thermocouple 308 may be disposed in the support body 302 for temperature measurement. The thermocouple 308 includes a first connector 310 made from a first conductor and a second connector 312 made from a second conductor. The first and second conductors are different conductors and may be made from any conductors suitable for thermocouples.

The first and second connectors 310, 312 extend out of the shaft 304. In one embodiment, an adaptor 326 may be coupled to the shaft 304. The first and second connectors 310, 312 may be secured in the adaptor 326 to further connect with a data collector. Traditionally, the first and second connectors 310, 312 may connect to leads to regular electrical wires and form cold junctions near the end of the shaft 304 or in the adaptor 326 for measurement. However, when the support body 302 and the shaft 304 are at high temperature, the cold junctions formed near the shaft 304 are also exposed to high temperature thus reducing accuracy of the thermocouple measurement.

In one embodiment, a thermocouple extension assembly 328 may be coupled to the first and second connectors 310, 312 to improve accuracy. The thermocouple extension assembly 328 includes a first extension 314 formed from the first conductor as with the first connector 310 of the thermocouple 308, and a second extension 316 formed from the second conductor as with the second connector 312 of the thermocouple 308. The first extension 314 has a first end 314a to connect with the first connector 310 and the second extension 316 has a first end 316a to connect with the second connector 312. Second ends 314b, 316b of the extension 314, 316 are then connected with connectors 320, 322 of a data collector 324. By connecting through the first and second extensions 314, 316, the thermocouple 308 effectively forms cold junctions at the second ends 314b, 316b of the extensions 314, 316. Because the second ends 314b, 316b may be positioned physically away from the heated region near the shaft 304, and because of the thermal gradient within the extensions 314, 316, the second ends 314b, 316b are not affected by the high temperature of the shaft 304, thus, achieve improved the accuracy of the thermocouple 308.

In one embodiment, the extensions 314, 316 may be disposed in a protective tube 306. The protective tube 306 may be designated for the extensions 314, 316. The protective tube 306 may also be extensions of the shaft 304 in certain substrate support designs.

In one embodiment, as shown in FIG. 3A, the extensions 314, 316 may be connected to the data collector 324 through an electrical union 318 to enable rotation of the substrate support assembly 300.

In another embodiment, as shown in FIG. 3B, a wireless unit 330 may be coupled to the extensions 314, 316. The wireless unit 330 may communicate with a receiver 332 which is disposed in a remote location. The wireless unit 330 may be disposed in the protective tube 306 to allow the protective tube 306 to rotate or move otherwise with no physical connections attached.

FIG. 4A is a schematic perspective view of a connection block 400 for use in a substrate support assembly according to one embodiment of the present disclosure. The connection block 400 may be used to provide convenient connections of sensors/or powers from a substrate support assembly, such as the substrate assembly 130 in FIG. 1. In one embodiment, the connection block 400 may be disposed inside the adaptor extension 184.

The connection block 400 includes a block body 402. The block body 402 may be formed from insulative materials, such as polymer. In one embodiment, the block body 402 is formed from PEEK (polyether ether ketone). One or more pairs of thermocouple connectors 404, 406 may be attached to the block body 402. The thermocouple connectors 404, 406 are formed from two conductors respectively matching the conductors of the thermocouple to be connected. As shown in FIG. 4A, thermocouples 410 may be coupled to the block body 402. A first connector 412 connects to the thermocouple connector 406, and a second connector 414 connects to the thermocouple connector 404. The first connector 412 and the thermocouple connector 406 are made of the same material while the second connector 414 and the thermocouple connector 404 are made of the same material. The connection block 400 may also include electrical connectors 408 to provide connections to other devices, such as heaters.

FIG. 4B is a schematic perspective view of a connection block 440 matching the connection block 400 of FIG. 4A. The connection block 440 includes a block body 442 having female connectors 444, 446, 448 formed therein. The female connectors 444, 446, 448 are positioned to match the locations of the connections 404, 406, 408 of the connection block 400. The connection block 400 may be connected to the connection block 440 by plugging the connectors 404, 406, 408 to the female connectors 444, 446, 448.

In one embodiment, the female connectors 444, 446 may be formed from the same materials of the thermocouples 410 and connected with thermocouple extensions 450, 452. Connectors 414, 404, 444, and extensions 450 may be formed from the same material. Connectors 412, 406, 446 and extensions 452 may be formed from the same material.

In one embodiment, the connection block 400 may be installed at the end of a shaft of a substrate support assembly, such as in the substrate support assemblies 130, 200, and 300 described above, to enable a convenient installation and removal, thus, providing easy service of the substrate support assembly.

Various embodiments of the present disclosure may be used alone or in combination. While the foregoing is directed to embodiments of the present disclosure, other and further embodiments of the disclosure may be devised without departing from the basic scope thereof, and the scope thereof is determined by the claims that follow.

1. A substrate support assembly, comprising:
a substrate support body having a substrate supporting surface;
a shaft extending from the substrate support body, wherein the shaft has a first end attached to the substrate support body and a second end away from the substrate support body, and the shaft is hollow having an inner volume extending from the first end to the second end;
a thermocouple attached to the substrate support body, wherein first and second connectors of the thermocouple extend down the inner volume to the second end of the shaft; and
a thermocouple extension attached to a second end of the shaft, wherein the thermocouple extension comprises:
a first extension having a first end for receiving the first connector of the thermocouple and a second end positioned away from the first end, wherein the first extension and the first connector are formed from the same material; and
a second extension having a first end for receiving the second connector of the thermocouple and a second end positioned away from the first end, wherein the second extension and the second connector are formed from the same material.

2. The substrate support assembly of claim 1, wherein the thermocouple extension further comprises a protective tube surrounding the first and second extensions, and the first ends and second ends of the extensions are attached to opposite ends of the protective tube.

3. The substrate support assembly of claim 2, wherein the protective tube is configured to connect with an electrical union to enable rotation of the protective tube and the shaft.

4. The substrate support assembly of claim 2, further comprising a wireless unit attached to the second ends of the first and second extensions.

5. A rotatable substrate support assembly, comprising:
a substrate support body having a substrate supporting surface, wherein the substrate support body comprises:
one or more sensors disposed in the substrate support body; and
one or more heating elements disposed in the substrate support body;
a shaft extending from the substrate support body, wherein one or more cooling channels are formed through the substrate support body and the shaft, and one or more vacuum channels are form through the substrate support body and the shaft; and
an extension assembly coupled to the shaft, wherein the extension assembly is configured to rotatably couple a power source with the one or more heaters, a data collector with the one or more sensors, a fluid source with the cooling channels, a vacuum source with the vacuum channels, and a rotation motor with the shaft.

6. The rotatable substrate support assembly of claim 5, wherein the extension assembly comprises:
a vacuum extension connected with the shaft, wherein the vacuum extension includes one or more vacuum outlets connected with the one or more vacuum channels, and the one or more vacuum outlets are open to an outer surface of the vacuum extension to connect with the vacuum source through a vacuum union.

7. The rotatable substrate support assembly of claim 5, wherein the extension assembly comprises:
a fluid extension connected with the shaft, wherein the fluid extension includes a fluid inlet and a fluid outlet connected with the one or more fluid channels, and the fluid inlet and outlet are open to an outer surface of the fluid extension to connect with the fluid source through a fluid union.

8. The rotatable substrate support assembly of claim 5, wherein the extension assembly comprises:
an electrical extension connected with the shaft, wherein the electrical extension connects the one or more sensors and the one or more heaters to the data collector and the power source through an electrical union.

9. The rotatable substrate support assembly of claim 5, further comprising a rotating motor having a rotor coupled to the extension assembly to rotate the shaft.

10. A semiconductor processing chamber, comprising:
a chamber body defining a processing volume;
a substrate support body disposed in the processing volume for supporting a substrate thereon, wherein the substrate support body comprises:
one or more sensors disposed in the substrate support body; and
one or more heating elements disposed in the substrate support body;
a shaft extending outside the processing volume from the substrate support body through an opening of the chamber body, wherein one or more cooling channels are formed through the substrate support body and the shaft, and one or more vacuum channels are form through the substrate support body and the shaft;
an extension assembly disposed outside the processing volume and coupled to the shaft, wherein the extension assembly is configured to rotatably couple a power source with the one or more heaters, a data collector with the one or more sensors, a fluid source with the cooling channels, and a vacuum source with the vacuum channels;
a rotation motor having a rotor coupled with the extension assembly and a stator coupled to a bracket; and
a vertical actuator coupled to the bracket, wherein the vertical actuator moves the substrate support body, the shaft, the extensions assembly and the rotation motor vertically.

11. The semiconductor processing chamber of claim 10, wherein the extension assembly further comprises:
a vacuum extension connected with the shaft, wherein the vacuum extension includes one or more vacuum outlets connected with the one or more vacuum channels, and the one or more vacuum outlets are open to an outer surface of the vacuum extension; and
a vacuum union rotatably coupled to the vacuum extension to connect the one or more vacuum outlets with a vacuum source.

12. The semiconductor processing chamber of claim 11, wherein the extension assembly comprises:
a fluid extension connected with the shaft, wherein the fluid extension includes a fluid inlet and a fluid outlet connected with the one or more fluid channels, and the fluid inlet and outlet are open to an outer surface of the fluid extension; and
a fluid union rotatably coupled to the fluid extension to connect with the fluid source the fluid inlet and outlet.

13. The semiconductor processing chamber of claim 12, wherein the extension assembly comprises:
an electrical extension connected with the shaft; and
an electrical union rotatably coupled to the electrical extension connecting the one or more sensors and the one or more heaters to the data collector and the power source through an electrical union.

14. The semiconductor processing chamber of claim 11, wherein in the one or more sensors comprise a thermocouple, the thermocouple comprises a first connector made of a first conductive material and a second connector made of a second conductive material, and the first and second connectors protrude from the shaft to connect with the extension assembly.

15. The semiconductor processing chamber of claim 14, wherein the extension assembly further comprises a thermocouple extension comprising:
a first extension having a first end for receiving the first connector of the thermocouple and a second end positioned away from the first end, wherein the first extension is formed from the first conductive material; and
a second extension having a first end for receiving the second connector of the thermocouple and a second end positioned away from the first end, wherein the second extension and the second connector are formed from the second conductive material.

16. The semiconductor processing chamber of claim 14, further comprising a connection block attached to the shaft, wherein the connection block comprises:
a block body; and
at least one pair of thermocouple connectors attached to the block body, wherein each pair of the thermocouple connectors comprises:
a first connector formed from a first conductive material; and
a second connector formed from a second conductive material different from the first conductive material, wherein the first and second conductive materials correspond to conductive materials used in the thermocouple.

17. The semiconductor processing chamber of claim 15, further comprising a protective tube surrounding the first and second extensions, wherein the first ends and second ends of the extensions are attached to opposite ends of the protective tube.

18. The semiconductor processing chamber of claim 17, further comprising a wireless unit attached to the second ends of the first and second extensions.

19. The semiconductor processing chamber of claim 16, further comprising a protective tube surrounding the first and second extensions, wherein the first ends and second ends of the extensions are attached to opposite ends of the protective tube.

20. The semiconductor processing chamber of claim 19, further comprising a wireless unit attached to the second ends of the first and second extensions.
